(19) United States
(12) Patent Application Publication
(10) Pub. No.: US 2014/0184184 A1
(43) Pub. Date: Jul. 3, 2014

(54) VOLTAGE DETECTING CIRCUIT AND VOLTAGE REGULATOR APPARATUS PROVIDED WITH SAME

(71) Applicant: PANASONIC CORPORATION, Osaka (JP)

(72) Inventors: Hiroshi YAJIMA, Osaka (JP); Hideyuki KIHARA, Kanagawa (JP); Takahiro UEHARA, Kyoto (JP)

(73) Assignee: PANASONIC CORPORATION, Osaka (JP)

(21) Appl. No.: 14/198,848

(22) Filed: Mar. 6, 2014

Related U.S. Application Data
(63) Continuation of application No. PCT/JP2012/001638, filed on Mar. 9, 2012.

(30) Foreign Application Priority Data
Sep. 22, 2011 (JP) 2011-207827

(51) Int. Cl. G01R 19/00; G05F 1/575

(52) U.S. Cl. CPC G01R 19/0084; G05F 1/575
USPC 323/274; 324/76.11

(57) ABSTRACT

A voltage detecting circuit including: a first current source including a first terminal connected to a first voltage input terminal; a second current source including a first terminal connected to ground potential VSS; and a first transistor including a first main terminal connected to a second terminal of the first current source, a second main terminal connected to a second terminal of the second current source and a detection output terminal, and a control terminal connected to a second voltage terminal. The first and the second current sources are configured such that a logic level of a detection output signal is determined based on whether one voltage applied to the first voltage terminal is higher or lower than a voltage obtained by adding a voltage of a difference between the first main terminal and control terminal of the first transistor to the other voltage applied to the second voltage terminal.

This is a continuation application under 35 U.S.C. 111(a) of pending prior International application No. PCT/JP2012/001638, filed on Mar. 9, 2012. The disclosure of Japanese Patent Application No. 2011-207827 filed on Sep. 22, 2011 including specification, drawings and claims is incorporated herein by reference in its entirety.

### BACKGROUND OF THE INVENTION

1. Field of the Invention

The present invention relates to a voltage detecting circuit and a voltage regulator apparatus provided with the voltage detecting circuit, and particularly to a voltage detecting circuit configured to detect a voltage reduction of a power supply voltage and a voltage regulator apparatus provided with the voltage detecting circuit.

2. Description of the Related Art

Mobile devices, such as mobile information terminals, operate using batteries as power supplies. To prevent malfunctions caused by the voltage reduction of the battery, an electronic circuit in the mobile device detects a power supply voltage and determines whether or not the detected power supply voltage is lower than a voltage necessary for a normal operation of the mobile device. In a case where the power supply voltage is lower than the voltage necessary for the normal operation of the mobile device, the electronic circuit stops the operation of the mobile device. Therefore, the mobile device needs to include a voltage detecting circuit configured to detect the voltage reduction of the power supply voltage.

FIG. 10 is a circuit diagram showing the configuration of a conventional voltage detecting circuit disclosed in Japanese Laid-Open Patent Application Publication No. 2009-198476. The voltage detecting circuit 10 shown in FIG. 10 outputs through a detection output terminal 4 a detection output voltage VOUT corresponding to a result of a comparison between a voltage corresponding to a power supply voltage VDD applied to a voltage input terminal 2 and a reference voltage Vref applied to a voltage input terminal 3. In a case where the voltage corresponding to the power supply voltage VDD is higher than the reference voltage Vref, the detection output voltage VOUT becomes the power supply voltage VDD that is defined as a high level. In a case where the voltage corresponding to the power supply voltage VDD is lower than the reference voltage Vref, the detection output voltage VOUT becomes a ground potential VSS that is defined as a low level.

A detection target voltage input terminal 20 is shorted to the voltage input terminal 2, so that the power supply voltage VDD applied to the voltage input terminal 2 is directly applied to the detection target voltage input terminal 20. The power supply voltage VDD applied to the detection target voltage input terminal 20 is divided by a resistance voltage dividing portion constituted by resistors R10 and R11. Then, a differential comparing portion constituted by MOS transistors M16, M17, M12, and M13 and a current source CS 10 compares the voltage obtained by the voltage dividing of the resistance voltage dividing portion with the reference voltage Vref. An output of the differential comparing portion is output through an output portion constituted by MOS transistors M14 and M15 and then output through an inverter circuit INV1 from the detection output terminal 4.

As above, by using the voltage detecting circuit 10 shown in FIG. 10, whether or not the voltage corresponding to the power supply voltage VDD is lower than the reference voltage Vref can be detected.

### SUMMARY OF THE INVENTION

The conventional voltage detecting circuit 10 is configured such that: the power supply voltage VDD is divided by the resistance voltage dividing portion constituted by the resistors R10 and R11; and the voltage obtained by this voltage dividing is input to one input terminal of the differential comparing portion. Since resistance values of the resistors R10 and R11 constituting the resistance voltage dividing portion originally vary, the voltage detection accuracy deteriorates by these variations of the resistance values.

To reduce influences of the variations of the resistance values, resistance widths of the resistors R10 and R11 may be set to be wide. However, in this case, the element areas of the resistors R10 and R11 increase, and this increases the area of a semiconductor integrated circuit on which the voltage detecting circuit is mounted. Further, to realize low current consumption of the voltage detecting circuit 10, the resistance values of the resistors R10 and R11 may be set to be large. However, in this case, the element areas of the resistors R10 and R11 further increases, and this further increases the area of the semiconductor integrated circuit.

The present invention was made to solve the above problems, and an object of the present invention is to provide a voltage detecting circuit whose area can be reduced without deteriorating the voltage detection accuracy and a voltage regulator apparatus provided with the voltage detecting circuit.

To solve the above-described conventional problems, a voltage detecting circuit according to one aspect of the present invention includes: a first voltage input terminal to which one of a detection target voltage and a reference voltage is applied; a second voltage input terminal to which the other of the detection target voltage and the reference voltage is applied; a detection output terminal through which a detection output signal is output, the detection output signal indicating a logic regarding whether or not the detection target voltage is lower than the reference voltage; a first current source including a first terminal connected to the first voltage input terminal; a second current source including a first terminal connected to ground; and a first transistor including a first main terminal connected to a second terminal of the first current source, a second main terminal connected to a second terminal of the second current source and the detection output terminal, and a control terminal connected to the second voltage input terminal, wherein the first current source and the second current source are configured such that a logic level of the detection output signal is determined based on whether said one voltage applied to the first voltage input terminal is higher or lower than a voltage obtained by adding a voltage of a difference between the first main terminal and control terminal of the first transistor to the other voltage applied to the second voltage input terminal.

According to this configuration, the threshold of the detection target voltage becomes a voltage obtained by adding to the reference voltage a voltage of a difference between the first main terminal and control terminal of the first transistor, and whether or not the detection target voltage is lower than the threshold can be detected. Since the voltage detecting circuit does not include a resistance voltage dividing portion configured to divide the detection target voltage, the deterioration of the voltage detection accuracy by the variation of the resistance value of the resistance voltage dividing portion does not occur. Since the current flowing through the resistance voltage dividing portion becomes unnecessary, the low current consumption can be realized. Further, since the resistance voltage dividing portion is unnecessary, the element area of the semiconductor integrated circuit can be reduced.

The above voltage detecting circuit may be configured such that: the first current source is constituted by a second transistor including a first main terminal connected to the first voltage input terminal and a second main terminal connected to the first main terminal of the first transistor, a first bias voltage being applied between the first main terminal and a control terminal of the second transistor; the second current source is constituted by a third transistor including a second main terminal connected to the second main terminal of the first transistor and a first main terminal connected to the ground, a second bias voltage being applied between the first main terminal and a control terminal of the third transistor; and a value as a ratio of a current drive ability of the second transistor to a current drive ability of the third transistor is larger than one, the value being obtained by multiplying by a predetermined coefficient a ratio of a product of a gate aspect ratio of the second transistor and a square of a difference between the first bias voltage and a threshold voltage of the second transistor to a product of a gate aspect ratio of the third transistor and a square of a difference between the second bias voltage and a threshold voltage of the third transistor.

According to this configuration, the current drive abilities of the second and third transistors can be set arbitrarily as long as a value as the ratio of the current drive ability of the second transistor to the current drive ability of the third transistor is larger than one, the value being obtained by multiplying by a predetermined coefficient a ratio of a product of the gate aspect ratio of the second transistor and a square of a difference between the first bias voltage and the threshold voltage of the second transistor to a product of the gate aspect ratio of the third transistor and a square of a difference between the second bias voltage and the threshold voltage of the third transistor. Therefore, the further low current consumption can be realized in such a manner that the current drive abilities of the second and third transistors are set to be small while maintaining a state where the ratio of the current drive ability of the second transistor to the current drive ability of the third transistor is higher than one.

The above voltage detecting circuit may further include a voltage shift portion provided between the second voltage input terminal and the control terminal of the first transistor, wherein the voltage shift portion may include: a fourth transistor including a first main terminal connected to the second voltage input terminal and a second main terminal connected to a control terminal of the fourth transistor and the control terminal of the first transistor; and a potential difference generating portion including a first terminal connected to the second main terminal of the fourth transistor and a second terminal connected to the ground, the potential difference generating portion being configured to generate a potential difference between the first main terminal and second main terminal of the fourth transistor.

According to this configuration, the threshold of the detection target voltage (the voltage of the first main terminal of the first transistor) is obtained by subtracting the voltage between the first main terminal and control terminal of the fourth transistor from the reference voltage and then adding the voltage between the first main terminal and control terminal of the first transistor. Therefore, the voltage between the first main terminal and control terminal of the first transistor and the voltage between the first main terminal and control terminal of the fourth transistor cancel each other, so that the threshold of the detection target voltage becomes the reference voltage. Here, the voltage between the first main terminal and control terminal of the first transistor is generally an error cause. Therefore, since this error cause is canceled from the threshold of the detection target voltage, the voltage detection accuracy improves.

The voltage detecting circuit may be configured such that gate aspect ratios of the first transistor and the fourth transistor are set such that a voltage difference between the first main terminal and control terminal of the fourth transistor and a voltage difference between the first main terminal and control terminal of the first transistor become equal to each other.

According to this configuration, since the voltage between the first main terminal and control terminal of the first transistor and the voltage between the first main terminal and control terminal of the fourth transistor surely cancel each other, the voltage detection accuracy further improves.

The above voltage detecting circuit may be configured such that the potential difference generating portion of the voltage shift portion is constituted by a resistor.

According to this configuration, since the resistance value of the resistor constituting the potential difference generating portion is set in accordance with the reference voltage, the current value of the fourth transistor can be set arbitrarily. Therefore, the further low current consumption can be realized in such a manner that the current value of the fourth transistor is set to be small.

The above voltage detecting circuit may further include a bias circuit configured to apply the first bias voltage between the first main terminal and control terminal of the second transistor of the first current source and apply the second bias voltage between the first main terminal and control terminal of the third transistor of the second current source, wherein: the bias circuit may include a fifth transistor including a first main terminal connected to the first main terminal of the second transistor and a second main terminal connected to a control terminal of the fifth transistor and the control terminal of the second transistor, a sixth transistor including a second main terminal connected to a control terminal of the sixth transistor and the control terminal of the third transistor and a first main terminal connected to the first main terminal of the third transistor, and a resistor connected between the second main terminal of the fifth transistor and the second main terminal of the sixth transistor; and a voltage difference between the first main terminal and control terminal of the fifth transistor, a voltage difference between the second main terminal and control terminal of the sixth transistor, and the gate aspect ratios of the second transistor, the third transistor, the fifth transistor, and the sixth transistor may be set such that the ratio of the current drive ability of the second transistor to the current drive ability of the third transistor becomes larger than one.

According to this configuration, a constant voltage source configured to apply a bias voltage between the first main terminal and control terminal of the second transistor and a constant voltage source configured to apply a bias voltage between the first main terminal and control terminal of the third transistor become unnecessary. The voltage difference between the first main terminal and control terminal of the fifth transistor, the voltage difference between the second main terminal and control terminal of the sixth transistor, and the gate aspect ratios of the second transistor, the third transistor, the fifth transistor, and the sixth transistor are set such that the ratio of the current drive ability of the second transistor to the current drive ability of the third transistor becomes higher than one. Therefore, even in a case where the resistance value is increased, and the current drive abilities of the second and third transistors are decreased, the magnitude relation between the current drive abilities of the second and third transistors does not change. On this account, the further low current consumption can be realized by increasing the resistance value while ensuring the circuit operations (functions) of the voltage detecting circuit.

The above voltage detecting circuit may be configured such that: the first current source is constituted by a first current mirror circuit including the second transistor and a seventh transistor, the second transistor including the first main terminal connected to the first voltage input terminal and the second main terminal connected to the first main terminal of the first transistor, the seventh transistor including a first main terminal connected to the first main terminal of the second transistor and a second main terminal connected to a control terminal of the seventh transistor, and the control terminal connected to the control terminal of the second transistor; the second current source is constituted by a second current mirror circuit including the third transistor, an eighth transistor, and a ninth transistor, the third transistor including the second main terminal connected to the second main terminal of the first transistor and the first main terminal connected to the ground, the eighth transistor including a second main terminal connected to a current source, a first main terminal connected to the ground, and a control terminal connected to the second main terminal of the eighth transistor, the ninth transistor including a second main terminal connected to the second main terminal of the seventh transistor, a first main terminal connected to the ground, and a control terminal connected to the control terminal of the third transistor and the control terminal of the eighth transistor; and mirror ratios of the second transistor and seventh transistor of the first current mirror circuit and mirror ratios of the third transistor, eighth transistor, and ninth transistor of the second current mirror circuit are set such that the ratio of the current drive ability of the second transistor to the current drive ability of the third transistor becomes larger than one.

According to this configuration, a constant voltage source configured to apply a bias voltage between the first main terminal and control terminal of the second transistor and a constant voltage source configured to apply a bias voltage between the first main terminal and control terminal of the third transistor become unnecessary. The magnitude relation between the current drive abilities of the second and third transistors is determined based on the gate aspect ratios of the transistors constituting the first and second current mirror circuits. Therefore, even in a case where the current value of the current source is changed, the magnitude relation between the second and third current drive abilities does not change. On this account, the further low current consumption can be realized by reducing the current value of the current source while ensuring the circuit operations of the voltage detecting circuit.

The above voltage detecting circuit may be configured such that: the second current mirror circuit further includes a tenth transistor including a second main terminal connected to the second main terminal of the fourth transistor, a first main terminal connected to the ground, and a control terminal connected to the control terminal of the eighth transistor; and a potential difference generating portion of a voltage shift portion is constituted by the tenth transistor.

According to this configuration, the current value of the third transistor can be set to a constant value regardless of the voltage value of the reference voltage.

To solve the above conventional problems, a voltage regulator apparatus according to another aspect of the present invention includes: the above voltage detecting circuit; and a voltage regulator circuit, wherein the voltage regulator circuit is configured such that an output therefrom is controlled in accordance with the detection output signal output from the detection output terminal of the voltage detecting circuit. Or, a voltage regulator apparatus includes a plurality of voltage detecting circuits, each of which is the above voltage detecting circuit, wherein: reference voltages applied to the first voltage input terminals or second voltage input terminals of the plurality of voltage detecting circuits are different from one another; and the voltage regulator circuit is configured such that an output therefrom is controlled in accordance with the detection output signals output from the detection output terminals of the plurality of voltage detecting circuits to become one of a plurality of states.

According to this configuration, it is possible to provide the voltage regulator apparatus provided with the voltage detecting circuit having the above effects.

The present invention can provide the voltage detecting circuit whose area can be reduced without deteriorating the voltage detection accuracy and the voltage regulator apparatus provided with the voltage detecting circuit.

The above object, other objects, features and advantages of the present invention will be made clear by the following detailed explanation of preferred embodiments with reference to the attached drawings.

### BRIEF DESCRIPTION OF THE DRAWINGS

FIG. 1 is a circuit diagram showing a configuration example of a voltage detecting circuit according to Embodiment 1 of the present invention.

FIG. 2 is a circuit diagram showing another configuration example of the voltage detecting circuit according to Embodiment 1 of the present invention.

FIG. 3 is a circuit diagram showing a configuration example of the voltage detecting circuit according to Embodiment 2 of the present invention.

FIG. 4 is a circuit diagram showing a configuration example of the voltage detecting circuit according to Embodiment 3 of the present invention.

FIG. 5 is a circuit diagram showing another configuration example of the voltage detecting circuit according to Embodiment 3 of the present invention.

FIG. 6 is a circuit diagram showing a configuration example of the voltage detecting circuit according to Embodiment 4 of the present invention.

FIG. 7 is a circuit diagram showing another configuration example of the voltage detecting circuit according to Embodiment 4 of the present invention.

FIG. 8 is a block diagram showing a configuration example of a voltage regulator apparatus according to Embodiment 5 of the present invention.

FIG. 9 is a block diagram showing another configuration example (modification example) of the voltage regulator apparatus according to Embodiment 5 of the present invention.

FIG. 10 is a circuit diagram showing a configuration of a conventional voltage detecting circuit.

### DESCRIPTION OF THE PREFERRED EMBODIMENTS

Hereinafter, embodiments of the present invention will be explained in reference to the drawings. In the following explanations and drawings, the same reference signs are used for the same or corresponding components, and repetitions of the same explanations are avoided.

### Embodiment 1

### Configuration of Voltage Detection Circuit

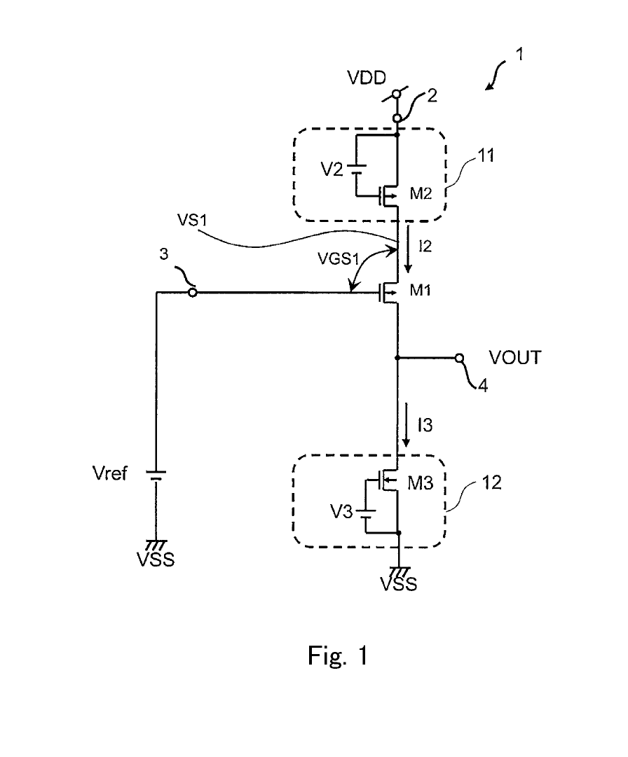

FIG. 1 is a circuit diagram showing a configuration example of a voltage detecting circuit according to Embodiment 1 of the present invention.

A voltage detecting circuit 1 shown in FIG. 1 includes: a voltage input terminal 2 (first voltage input terminal) to which a power supply voltage VDD (detection target voltage) is applied; a voltage input terminal 3 (second voltage input terminal) to which a reference voltage Vref is applied; and a detection output terminal 4 through which a detection output signal is output, the detection output signal indicating a detection result of the power supply voltage VDD applied to the voltage input terminal 2.

The voltage detecting circuit 1 shown in FIG. 1 further includes: a current source 11 (first current source) including a first terminal connected to the voltage input terminal 2; a current source 12 (second current source) including a first terminal connected to a ground potential VSS; and a PMOS transistor M1 (first transistor) including a source terminal (first main terminal) connected to a second terminal of the current source 11, a drain terminal (second main terminal) connected to a second terminal of the current source 12 and the detection output terminal 4, and a gate terminal (control terminal) connected to the voltage input terminal 3.

The current source 11 is constituted by a PMOS transistor M2 (second transistor) including a source terminal (first main terminal) connected to the voltage input terminal 2 and a drain terminal (second main terminal) connected to the source terminal of the PMOS transistor M1, a voltage (first bias voltage) of a constant voltage source V2 being applied between the source terminal and a gate terminal (control terminal) of the PMOS transistor M2.

The current source 12 is constituted by an NMOS transistor M3 (third transistor) including a drain terminal (second main terminal) connected to the drain terminal of the PMOS transistor M1 and a source terminal (first main terminal) connected to the ground potential VSS, a voltage (second bias voltage) of a constant voltage source V3 being applied between the source terminal and a gate terminal of the NMOS transistor M3.

The current source 11 and the current source 12 are configured such that a logic level of a detection output voltage VOUT is determined by a comparison between the power supply voltage VDD (one voltage) applied to the voltage input terminal 2 and a voltage (VS1) obtained by adding a gate-to-source voltage (VGS1) of the PMOS transistor M1 to the reference voltage Vref (the other voltage) applied to the voltage input terminal 3.

Specifically, the bias voltages V2 and V3 and gate aspect ratios of the PMOS transistor M2 and the NMOS transistor M3 are set such that a ratio of a current drive ability of the PMOS transistor M2 to the current drive ability of the NMOS transistor M3 becomes higher than one. The gate aspect ratio denotes a ratio between a gate width (W) of a transistor and a gate length (L) of the transistor and is represented by W/L.

In other words, the bias voltage V2 applied between a gate and source of the PMOS transistor M2, the bias voltage V3 applied between a gate and source of the NMOS transistor M3, or the gate aspect ratios of the PMOS transistor M2 and the NMOS transistor M3 are set such that a drain current value (I2) that can flow through the PMOS transistor M2 becomes larger than a drain current value (I3) that can flow through the NMOS transistor M3.

A drain current Id in a non-saturated region of a MOS transistor is typically represented by Formula 1 below.

Id=(½)*μs*Cox*(W/L)*(VGS−VTH)̂2 (Formula 1)

In Formula 1, “Cox” denotes a gate oxide film capacity of the MOS transistor, “μs” denotes a surface mobility of a majority carrier, “W/L” denotes a gate aspect ratio, “VGS” denotes a gate-to-source voltage, and “VTH” denotes a threshold voltage. Therefore, parameters for adjusting the current drive ability are the surface mobility μs of the majority carrier, the gate oxide film capacity Cox, the gate aspect ratio (W/L), the bias voltage that is the gate-to-source voltage VGS, and the threshold voltage VTH. Here, designed values of the surface mobility μs of the majority carrier, the gate oxide film capacity Cox, and the threshold voltage VTH are determined by a semiconductor process used when fabricating the voltage detecting circuit. The surface mobility μs of the majority carrier, the gate oxide film capacity Cox, and the threshold voltage VTH differ between the PMOS transistor and the NMOS transistor.

Therefore, the ratio of the current drive ability of the PMOS transistor M2 to the current drive ability of the NMOS transistor M3 can be simplistically verified by a value obtained by multiplying a ratio by a predetermined coefficient, the ratio being a ratio of a product of the gate aspect ratio of the PMOS transistor M2 and a square of a difference (V2−VTH2) between the bias voltage V2 and a threshold voltage VTH2 of the PMOS transistor M2 to a product of the gate aspect ratio of the NMOS transistor M3 and a square of a difference (V3−VTH3) between the bias voltage V3 and a threshold voltage VTH3 of the NMOS transistor M3. The predetermined coefficient is a value corresponding to a ratio of a product of the surface mobility μs of a positive hole of the PMOS transistor M2 and the gate oxide film capacity Cox of the PMOS transistor M2 to a product of the surface mobility μs of an electron of the NMOS transistor M3 and the gate oxide film capacity Cox of the NMOS transistor M3. As described above, the predetermined coefficient can be determined by a semiconductor process used when fabricating the voltage detecting circuit.

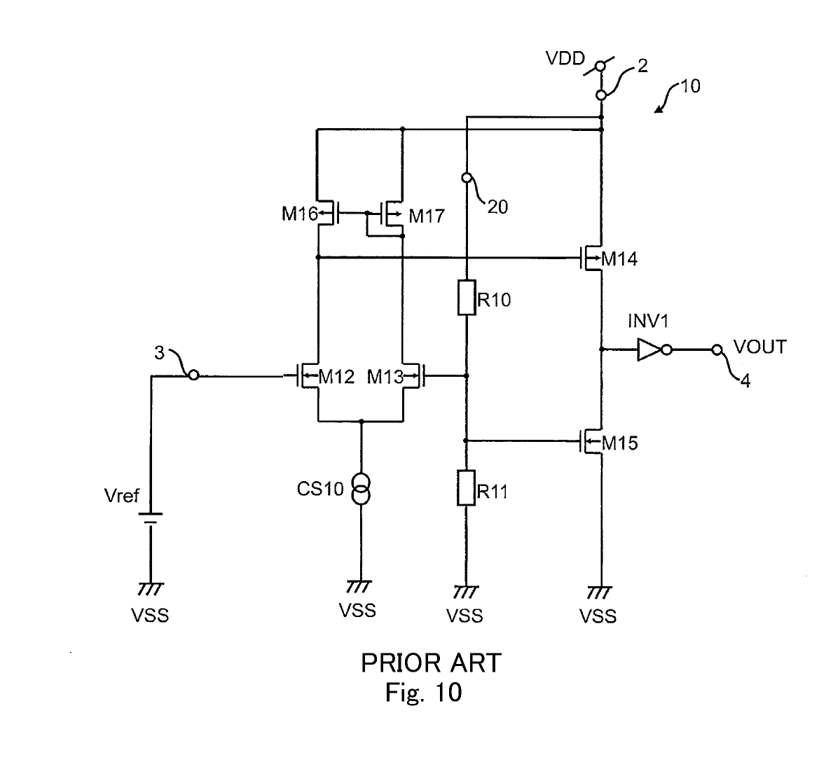

As with the conventional voltage detecting circuit 10 shown in FIG. 10, an inverter circuit may be connected to the detection output terminal 4.

Operations of Voltage Detection Circuit

A summary of the operations of the voltage detecting circuit 1 will be explained. By using a relation of a source-to-drain voltage of the PMOS transistor M2, the voltage detecting circuit 1 compares the power supply voltage VDD applied to the voltage input terminal 2 with a threshold of the detection target voltage (power supply voltage VDD) corresponding to the reference voltage Vref applied to the voltage input terminal 3. Then, the voltage detecting circuit 1 outputs from the detection output terminal 4 the detection output voltage VOUT corresponding to the result of the comparison. In a case where the power supply voltage VDD is higher than the threshold corresponding to the reference voltage Vref, the detection output voltage VOUT becomes the power supply voltage VDD that is defined as a high level. In a case where the power supply voltage VDD is equal to or lower than the threshold corresponding to the reference voltage Vref, the detection output voltage VOUT becomes the ground potential VSS that is defined as a low level.

Detailed operations in the voltage detecting circuit 1 will be explained. The voltage (VS1) of the source terminal of the PMOS transistor M1 is obtained by adding the gate-to-source voltage (VGS1) of the PMOS transistor M1 to the reference voltage Vref and is represented by Formula 2 below.

VS1=Vref+VGS1 (Formula 2)

The threshold of the detection target voltage corresponding to the reference voltage Vref is the voltage (VS1) of the source terminal of the PMOS transistor M1. Therefore, the threshold of the detection target voltage corresponding to the reference voltage Vref is represented by “Vref+VGS1” as in Formula 2.

First, a case is assumed where the power supply voltage VDD is higher than the threshold Vref+VGS1 as represented by Formula 3 below.

VDD>Vref+VGS1 (Formula 3)

In this case, the source-to-drain voltage of the PMOS transistor M2 becomes a positive value, so that the drain current I2 of the PMOS transistor M2 intends to flow through the PMOS transistor M1 as the drain current I3 of the NMOS transistor M3. Here, various transistor constants are set such that the drain current value (I2) flowing through the PMOS transistor M2 becomes larger than the drain current value (I3) flowing through the NMOS transistor M3. Therefore, the NMOS transistor M3 intends to draw from the PMOS transistor M2 a current that exceeds the ability of the NMOS transistor M3. On this account, the potential of the detection output terminal 4 increases to approach the power supply voltage VDD that is defined as the high level.

Next, a case is assumed where the power supply voltage VDD is equal to or lower than the threshold Vref+VGS1 as in Formula 4 below.

VDD≦Vref+VGS1 (Formula 4)

In this case, the source-to-drain voltage of the PMOS transistor M2 becomes zero or a negative value, so that the drain current I2 of the PMOS transistor M2 does not flow. To be specific, the drain current value (I2) of the PMOS transistor M2 becomes zero, and the drain current value of the PMOS transistor M1 also becomes zero. As a result, the potential of the detection output terminal 4 decreases to approach the ground potential VSS that is defined as the low level.

As above, whether or not the power supply voltage VDD is lower than the threshold Vref+VGS1 can be detected by adopting the voltage detecting circuit 1 shown in FIG. 1. Further, the voltage detecting circuit 1 shown in FIG. 1 does not include the resistance voltage dividing portion (resistors R10 and R11) configured to divide the detection target voltage, such as the power supply voltage VDD of the conventional voltage detecting circuit 10 shown in FIG. 10. Therefore, the problem of the conventional voltage detecting circuit 10, that is, the deterioration of the voltage detection accuracy by the variation of the resistance value of the resistance voltage dividing portion does not occur. Since the voltage detecting circuit 1 does not include the resistance voltage dividing portion (resistors R10 and R11), the current flowing through the resistance voltage dividing portion (resistors R10 and R11) becomes unnecessary, so that the low current consumption can be realized. Further, since the voltage detecting circuit 1 does not include the resistance voltage dividing portion (resistors R10 and R11), the element area of the semiconductor integrated circuit can be reduced.

As long as the drain current value I2 is larger than the drain current value I3, the drain current value (I2) of the PMOS transistor M2 and the drain current value (I3) of the NMOS transistor M3 can be set arbitrarily. Therefore, the further low current consumption can be realized in such a manner that the drain current value (I2) of the PMOS transistor M2 and the drain current value (I3) of the NMOS transistor M3 are set to be small while maintaining a state where the drain current value I2 is larger than the drain current value I3.

### Modification Example of Embodiment 1

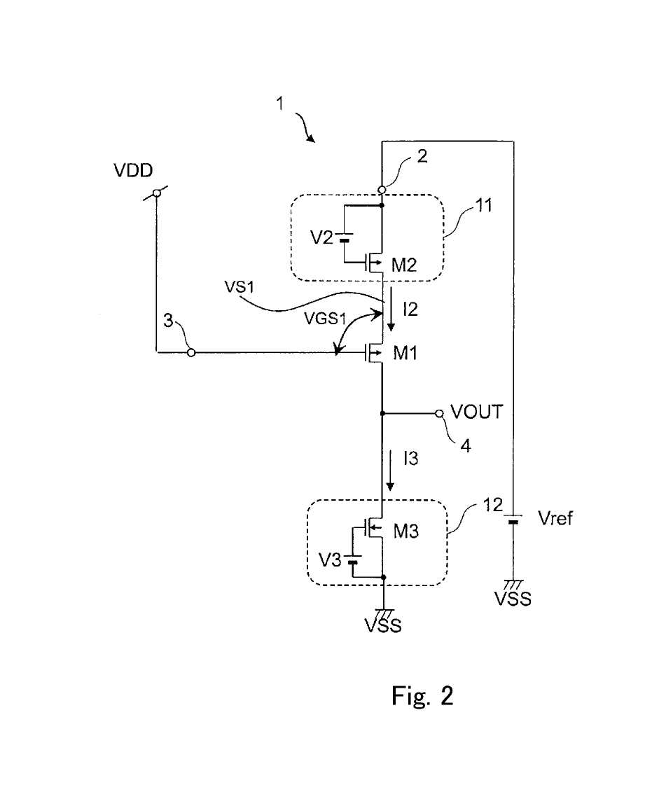

FIG. 2 is a circuit diagram showing another configuration example (modification example) of the voltage detecting circuit according to Embodiment 1 of the present invention. An internal configuration of the voltage detecting circuit 1 shown in FIG. 2 is the same as that of the voltage detecting circuit according to Embodiment 1 shown in FIG. 1 except that the voltages respectively applied to the voltage input terminals 2 and 3 are reversed. To be specific, the reference voltage Vref is applied to the voltage input terminal 2, and the power supply voltage VDD is applied to the voltage input terminal 3.

A summary of the operations of the voltage detecting circuit 1 shown in FIG. 2 will be explained. The voltage detecting circuit 1 shown in FIG. 2 compares the threshold of the detection target voltage corresponding to the reference voltage Vref applied to the voltage input terminal 2 with the power supply voltage VDD applied to the voltage input terminal 3. Then, the voltage detecting circuit 1 outputs from the detection output terminal 4 the detection output voltage VOUT corresponding to the result of the comparison. In a case where the power supply voltage VDD is equal to or higher than the threshold corresponding to the reference voltage Vref, the detection output voltage VOUT becomes the ground potential VSS that is defined as the low level. In a case where the power supply voltage VDD is lower than the threshold corresponding to the reference voltage Vref, the detection output voltage VOUT becomes the power supply voltage VDD that is defined as the high level. To be specific, the logic of the detection output voltage VOUT of Embodiment 1 is reversed in this modification example.

Detailed operations in the voltage detecting circuit 1 shown in FIG. 2 will be explained. The voltage (VS1) of the source terminal of the PMOS transistor M1 is obtained by adding the gate-to-source voltage (VGS1) of the PMOS transistor M1 to the power supply voltage VDD and is represented by Formula 5 below.

VS1=VDD+VGS1 (Formula 5)

The relation between the drain current value (I2) of the PMOS transistor M2 and the drain current value (I3) of the NMOS transistor M3 is the same as that in Embodiment 1 shown in FIG. 1.

A case is assumed where the voltage (VS1=VDD+VGS1) of the source terminal of the PMOS transistor M1 is equal to or higher than the reference voltage Vref as represented by Formula 6 below.

VDD+VGS1≧Vref (Formula 6)

In this case, the source-to-drain voltage of the PMOS transistor M2 becomes zero or a negative value, so that the drain current I2 of the PMOS transistor M2 does not flow. To be specific, the drain current value of the PMOS transistor M2 becomes zero, and the drain current value of the PMOS transistor M1 also becomes zero. Therefore, the potential of the detection output terminal 4 decreases to approach the ground potential VSS that is defined as the low level. Formula 6 can be represented as Formula 7 below.

VDD≧Vref−VGS1 (Formula 7)

To be specific, in a case where the power supply voltage VDD is equal to or higher than the threshold Vref−VGS1, the detection output voltage VOUT becomes the ground potential VSS that is defined as the low level.

A case is assumed where the voltage (VS1=VDD+VGS1) of the source terminal of the PMOS transistor M1 is lower than the reference voltage Vref as represented by Formula 8 below.

VDD+VGS1<Vref (Formula 8)

In this case, the source-to-drain voltage of the PMOS transistor M2 becomes a positive value, so that the drain current I2 of the PMOS transistor M2 intends to flow through the PMOS transistor M1 as the drain current I3 of the NMOS transistor M3. Here, various transistor constants are set such that the drain current value (I2) of the PMOS transistor M2 becomes larger than the drain current value (I3) of the NMOS transistor M3. Therefore, the NMOS transistor M3 intends to draw from the PMOS transistor M2 a current that exceeds the ability of the NMOS transistor M3. On this account, the potential of the detection output terminal 4 increases to approach the power supply voltage VDD that is defined as the high level. Formula 8 can be represented as Formula 9 below.

VDD<Vref−VGS1 (Formula 9)

To be specific, in a case where the power supply voltage VDD is lower than the threshold Vref−VGS1, the detection output voltage VOUT becomes the power supply voltage VDD that is defined as the high level.

As above, by adopting the voltage detecting circuit 1 shown in FIG. 2, it is possible to detect that the power supply voltage VDD is lower than the threshold Vref−VGS1. Modification Example of Embodiment 1 is different from Embodiment 1 shown in FIG. 1 regarding the threshold of the power supply voltage VDD and the reversal of the logic level of the detection output voltage VOUT. Modification Example of Embodiment 1 has the same effects as Embodiment 1 shown in FIG. 1.

As with the conventional voltage detecting circuit 10 shown in FIG. 10, an inverter circuit may be connected to the detection output terminal 4. In this case, since the logic of the detection output voltage VOUT of the detection output terminal 4 is reversed, it becomes the same as the logic of the detection output voltage VOUT of Embodiment 1 shown in FIG. 1.

### Embodiment 2

### Configuration of Voltage Detection Circuit

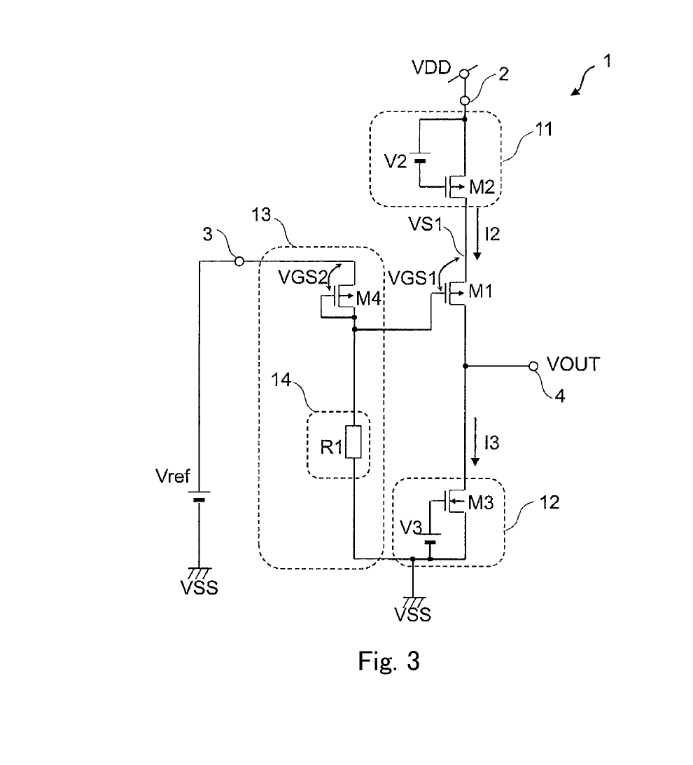

FIG. 3 is a circuit diagram showing a configuration example of the voltage detecting circuit according to Embodiment 2 of the present invention. The voltage detecting circuit according to Embodiment 2 is different in configuration from the voltage detecting circuit according to Embodiment 1 shown in FIG. 1 in that a voltage shift portion 13 is interposed between the voltage input terminal 3 and the gate terminal of the PMOS transistor M1.

The voltage shift portion 13 includes a PMOS transistor M4 (fourth transistor) and a potential difference generating portion 14. The PMOS transistor M4 includes a source terminal (first main terminal) connected to the voltage input terminal 3 (second voltage input terminal) and a drain terminal (second main terminal) connected to a gate terminal (control terminal) of the PMOS transistor M4 and the gate terminal of the PMOS transistor M1 (first transistor). The potential difference generating portion 14 includes a first terminal connected to the drain terminal (second main terminal) of the PMOS transistor M4 and a second terminal connected to the ground potential VSS and is configured to generate a potential difference between the source and drain of the PMOS transistor M4. The potential difference generating portion 14 is constituted by a resistor R1 but may be constituted by a current source. Further, the gate aspect ratios of the PMOS transistors M1 and M4 are set such that a gate-to-source voltage (VGS2) of the PMOS transistor M4 and the gate-to-source voltage (VGS1) of the PMOS transistor M1 become equal to each other.

Operations of Voltage Detection Circuit

A summary of the operations of the voltage detecting circuit 1 shown in FIG. 3 will be explained.

The operations of the voltage detecting circuit 1 according to Embodiment 2 are different from those of the voltage detecting circuit 1 according to Embodiment 1 shown in FIG. 1 regarding the threshold of the detection target voltage. The voltage (VS1) of the source terminal of the PMOS transistor M1 is obtained by subtracting the gate-to-source voltage (VGS2) of the PMOS transistor M4 of the voltage shift portion 13 from the reference voltage Vref and then adding the gate-to-source voltage (VGS1) of the PMOS transistor M1 and is represented by Formula 10 below.

VS1=Vref−VGS2+VGS1 (Formula 10)

Here, since the gate aspect ratios of the PMOS transistors M1 and M4 are set such that the gate-to-source voltage (VGS2) of the PMOS transistor M4 and the gate-to-source voltage (VGS1) of the PMOS transistor M1 become equal to each other, Formula 10 can be represented by Formula 11 below.

VS1=Vref (Formula 11)

To be specific, the voltage VS 1 of the source terminal of the PMOS transistor M1, that is, the threshold of the detection target voltage becomes only the reference voltage Vref.

In a case where the power supply voltage VDD is higher than the threshold Vref, the source-to-drain voltage of the PMOS transistor M2 becomes a positive value, so that the drain current I2 of the PMOS transistor M2 intends to flow through the PMOS transistor M1 as the drain current I3 of the NMOS transistor M3. Here, various transistor constants are set such that the drain current value (I2) of the PMOS transistor M2 becomes larger than the drain current value (I3) of the NMOS transistor M3. Therefore, the NMOS transistor M3 intends to draw from the PMOS transistor M2 a current that exceeds the ability of the NMOS transistor M3. On this account, the potential of the detection output terminal 4 increases to approach the power supply voltage VDD that is defined as the high level.

In a case where the power supply voltage VDD is equal to or lower than the threshold Vref, the source-to-drain voltage of the PMOS transistor M2 becomes zero or a negative value, so that the drain current I2 of the PMOS transistor M2 does not flow. To be specific, the drain current value (I2) of the PMOS transistor M2 becomes zero, and the drain current value of the MOS transistor M1 also becomes zero. Therefore, the potential of the detection output terminal 4 decreases to approach the ground potential VSS that is defined as the low level.

As above, whether or not the power supply voltage VDD is lower than the threshold Vref can be detected by adopting the voltage detecting circuit 1 shown in FIG. 3. Embodiment 2 has the same effects as Embodiment 1 shown in FIG. 1. The resistor R1 connected as the potential difference generating portion 14 to the drain terminal of the PMOS transistor M4 is used to set the drain current value of the PMOS transistor M4. To be specific, by setting the resistance value of the resistor R1 in accordance with the reference voltage Vref, the drain current value of the PMOS transistor M4 can be set arbitrarily. Therefore, the further low current consumption can be realized in such a manner that the drain current value of the PMOS transistor M4 is set to be small.

### Modification Example of Embodiment 2

The gate aspect ratios of the PMOS transistors M1 and M4 are set such that the gate-to-source voltage (VGS2) of the PMOS transistor M4 and the gate-to-source voltage (VGS1) of the PMOS transistor M1 become equal to each other. These gate aspect ratios of the PMOS transistors M1 and M4 are not specific values. As long as the gate-to-source voltage (VGS2) of the PMOS transistor M4 and the gate-to-source voltage (VGS1) of the PMOS transistor M1 are equal to each other, the gate aspect ratios of the PMOS transistors M1 and M4 can be set arbitrarily, and the threshold of the detection target voltage can be set to an arbitrary value in accordance with the reference voltage Vref.

In addition, as with Modification Example of Embodiment 1 shown in FIG. 2, the reference voltage Vref may be applied to the voltage input terminal 2, and the power supply voltage VDD may be applied to the voltage input terminal 3. Further, as with the conventional voltage detecting circuit 10 shown in FIG. 10, an inverter circuit may be connected to the detection output terminal 4.

### Embodiment 3

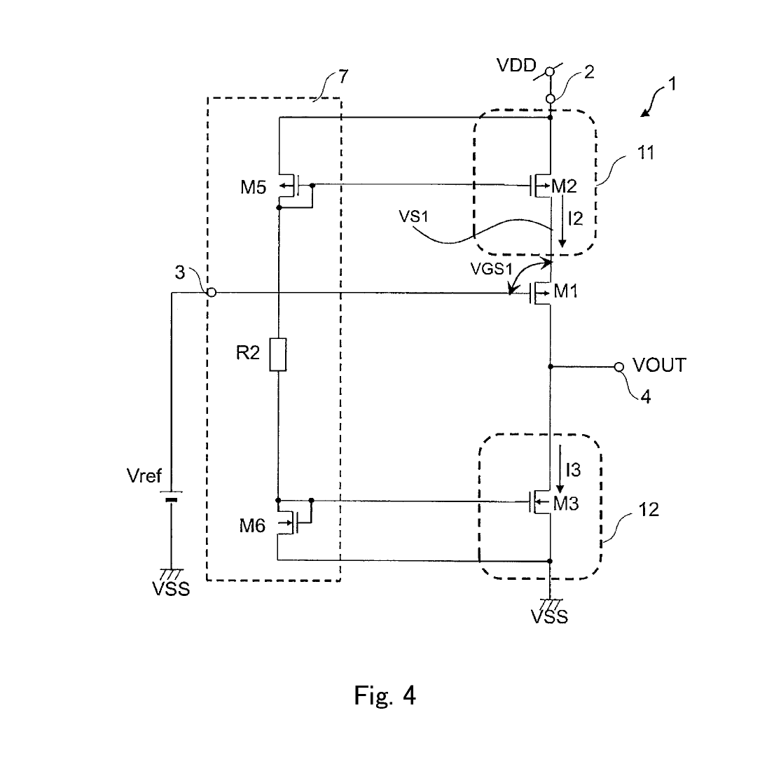

FIG. 4 is a circuit diagram showing a configuration example of the voltage detecting circuit according to Embodiment 3 of the present invention. The voltage detecting circuit according to Embodiment 3 is different in configuration from the voltage detecting circuit according to Embodiment 1 shown in FIG. 1 in that the constant voltage source V2 configured to apply the bias voltage between the gate and source of the PMOS transistor M2 and the constant voltage source V3 configured to apply the bias voltage between the gate and source of the NMOS transistor M3 are replaced with a bias circuit 7. To be specific, the bias circuit 7 is configured to apply the bias voltage (first bias voltage) between the gate and source of the PMOS transistor M2 (second transistor) of the current source 11 (first current source) and apply the bias voltage (second bias voltage) between the gate and source of the NMOS transistor M3 (third transistor) of the current source 12 (second current source).

Specifically, the bias circuit 7 includes a PMOS transistor M5 (fifth transistor), an NMOS transistor M6 (sixth transistor), and a resistor R2. The PMOS transistor M5 (fifth transistor) includes a source terminal (first main terminal) connected to the source terminal of the PMOS transistor M2 (second transistor) and a drain terminal (second main terminal) connected to a gate terminal (control terminal) of the PMOS transistor M5 and the gate terminal of the PMOS transistor M2. The NMOS transistor M6 (sixth transistor) includes a drain terminal (second main terminal) connected to a gate terminal (control terminal) of the NMOS transistor M6 and the gate terminal of the NMOS transistor M3 and a source terminal (first main terminal) connected to the source terminal (first main terminal) of the NMOS transistor M3. The resistor R2 is connected between the drain terminal of the PMOS transistor M5 and the drain terminal of the NMOS transistor M6. With this configuration, the gate-to-source voltage of the PMOS transistor M5 is applied between the gate and source of the PMOS transistor M2 as the bias voltage, and the gate-to-source voltage of the NMOS transistor M6 is applied between the gate and source of the NMOS transistor M3 as the bias voltage.

Further, in the bias circuit 7, the gate-to-source voltage of the PMOS transistor M5, the gate-to-source voltage of the NMOS transistor M6, and the gate aspect ratios of the PMOS transistor M2, the NMOS transistor M3, the PMOS transistor M5, and the NMOS transistor M6 are set such that the ratio of the current drive ability of the PMOS transistor M2 to the current drive ability of the NMOS transistor M3 becomes higher than one. Specifically, the gate aspect ratios of the PMOS transistor M5 and the NMOS transistor M6 are set such that an absolute value of the gate-to-source voltage of the PMOS transistor M5 becomes larger than an absolute value of the gate-to-source voltage of the NMOS transistor M6. Next, the gate aspect ratios of the PMOS transistor M5 and the PMOS transistor M2 are set to 1:1, and the gate aspect ratios of the NMOS transistor M6 and the NMOS transistor M3 are set to 1:1.

With this, the voltage detecting circuit 1 according to Embodiment 3 can realize the same functions as the voltage detecting circuit 1 according to Embodiment 1 shown in FIG. 1. Since the constant voltage source V2 and the constant voltage source V3 are replaced with the bias circuit 7, the constant voltage source V2 and the constant voltage source V3 become unnecessary. A magnitude relation between the drain current value (I2) of the PMOS transistor M2 and the drain current value (I3) of the NMOS transistor M3 is determined based on the gate aspect ratios of the PMOS transistor M2, the NMOS transistor M3, the PMOS transistor M5, and the NMOS transistor M6. Therefore, even in a case where the value of the resistor R2 is increased, and the drain current value (I2) of the PMOS transistor M2 and the drain current value (I3) of the NMOS transistor M3 are decreased, the magnitude relation between the drain current value (I2) of the PMOS transistor M2 and the drain current value (I3) of the NMOS transistor M3 does not change. On this account, the low current consumption can be realized by increasing the value of the resistor R2 while ensuring the circuit operations (functions) of the voltage detecting circuit 1.

### Modification Example of Embodiment 3

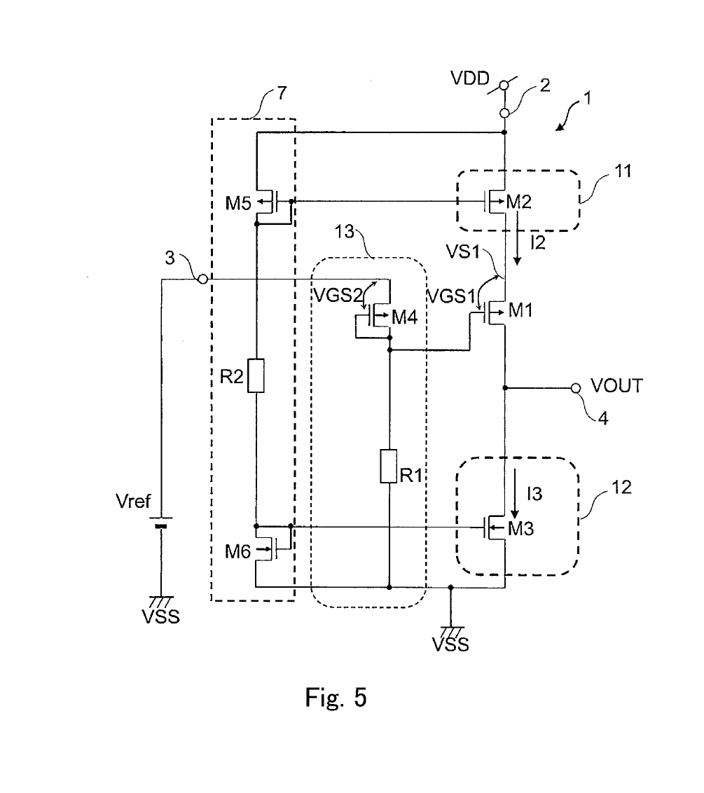

FIG. 5 is a circuit diagram showing another configuration example (modification example) of the voltage detecting circuit according to Embodiment 3 of the present invention.

Modification Example of Embodiment 3 is different in configuration from Embodiment 3 shown in FIG. 4 in that the voltage shift portion 13 is interposed between the voltage input terminal 3 and the gate terminal of the PMOS transistor M1 as with Embodiment 2 shown in FIG. 3. The voltage shift portion 13 is the same in configuration as the voltage shift portion 13 shown in FIG. 3. The voltage detecting circuit 1 shown in FIG. 4 has the same effects as the voltage detecting circuit 1 shown in FIG. 3.

The gate-to-source voltage of the PMOS transistor M5, the gate-to-source voltage of the NMOS transistor M6, and the gate aspect ratios of the PMOS transistor M2, the NMOS transistor M3, the PMOS transistor M5, and the NMOS transistor M6 are not specific values and may be set arbitrarily as long as the ratio of the current drive ability of the PMOS transistor M2 to the current drive ability of the NMOS transistor M3 is higher than one.

As with Modification Example of Embodiment 1 shown in FIG. 2, the reference voltage Vref may be applied to the voltage input terminal 2, and the power supply voltage VDD may be applied to the voltage input terminal 3.

In the configurations shown in FIGS. 4 and 5, the drain current value I2 of the PMOS transistor M2 and the drain current value I3 of the NMOS transistor M3 are set by the resistor R2 but may be set by a current source instead of the resistor.

### Embodiment 4

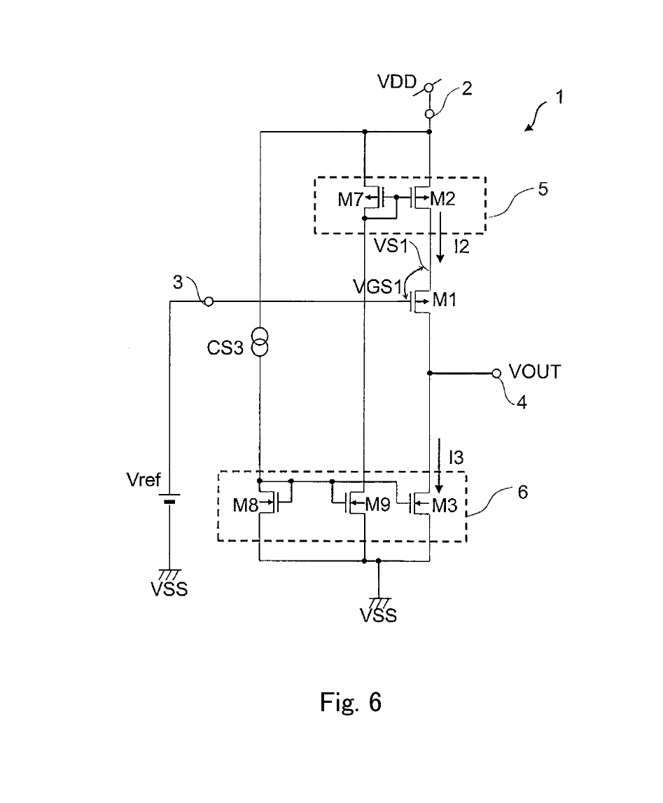

FIG. 6 is a circuit diagram showing a configuration example of the voltage detecting circuit according to Embodiment 4 of the present invention. Embodiment 4 is different in configuration from Embodiment 2 shown in FIG. 3 in that: the current source 11 constituted by the PMOS transistor M2 and the constant voltage source V2 is replaced with a current mirror circuit 5 (first current mirror circuit) constituted by the PMOS transistor M2 (second transistor) and a PMOS transistor M7 (seventh transistor); and the current source 12 constituted by the NMOS transistor M3 and the constant voltage source V3 is replaced with a current mirror circuit 6 (second current mirror circuit) constituted by the NMOS transistor M3 (third transistor) and NMOS transistors M8 and M9 (eighth and ninth transistors).

Specifically, the current mirror circuit 5 is constituted by: the PMOS transistor M2 including a source terminal (first main terminal) connected to the voltage input terminal 2 and a drain terminal (second main terminal) connected to the source terminal of the PMOS transistor M1; and the PMOS transistor M7 including a source terminal (first main terminal) connected to the source terminal of the PMOS transistor M2, a drain terminal (second main terminal) connected to a gate terminal of the PMOS transistor M7, and the gate terminal connected to the gate terminal of the PMOS transistor M2.

The current mirror circuit 6 is constituted by: the NMOS transistor M3 including a drain terminal (second main terminal) connected to the drain terminal of the PMOS transistor M1 and a source terminal (first main terminal) connected to the ground potential VSS; an NMOS transistor M8 including a drain terminal (second main terminal) connected to a current source CS3, a source terminal (first main terminal) connected to the ground potential VSS, and a gate terminal (control terminal) connected to the drain terminal of the NMOS transistor M8; and an NMOS transistor M9 including a drain terminal (second main terminal) connected to the drain terminal of the PMOS transistor M7, a source terminal (first main terminal) connected to the ground potential VSS, and a gate terminal (control terminal) connected to the gate terminals of the NMOS transistors M3 and M8.

Further, a mirror ratio of the current mirror circuit 5 (the gate aspect ratios of the PMOS transistors M2 and M7) and a mirror ratio of the current mirror circuit 6 (the gate aspect ratios of the NMOS transistors M3, M8, and M9) are set such that the ratio of the current drive ability of the PMOS transistor M2 to the current drive ability of the NMOS transistor M3 becomes higher than one.

For example, the gate aspect ratios of the NMOS transistors M8, M9, and M3 constituting the current mirror circuit 6 are set as represented by Formula 12 below.

M8:M9:M3=1:1:1 (Formula 12)

The gate aspect ratios of the PMOS transistors M7 and M2 constituting the current mirror circuit 5 are set as represented by Formula 13 below.

M7:M2=1:2 (Formula 13)

In this case, the drain current value (I2) of the PMOS transistor M2 is twice the drain current value (I3) of the NMOS transistor M3. The settings of the gate aspect ratios of the NMOS transistors M8, M9, and M3 and the gate aspect ratios of the PMOS transistors M7 and M2 are not limited to the above and may be any settings as long as the drain current value (I2) of the PMOS transistor M2 is larger than the drain current value (I3) of the NMOS transistor M3.

As above, since the current source 11 constituted by the PMOS transistor M2 and the constant voltage source V2 and the current source 12 constituted by the NMOS transistor M3 and the constant voltage source V3 are replaced with the current mirror circuit 5 and the current mirror circuit 6, the constant voltage source V2 and the constant voltage source V3 become unnecessary. The drain current value (I2) of the PMOS transistor M2 is determined in accordance with the gate aspect ratios of the transistors constituting the current mirror circuit 5, and the drain current value (I3) of the NMOS transistor M3 is determined in accordance with the gate aspect ratios of the transistors constituting the current mirror circuit 6. Therefore, even in a case where the current value of the current source CS3 is changed, the magnitude relation between the drain current value (I2) of the PMOS transistor M2 and the drain current value (I3) of the NMOS transistor M3 does not change. On this account, the low current consumption can be realized by reducing the current value of the current source CS3 while ensuring the circuit operations of the voltage detecting circuit 1 shown in FIG. 6.

### Modification Example of Embodiment 4

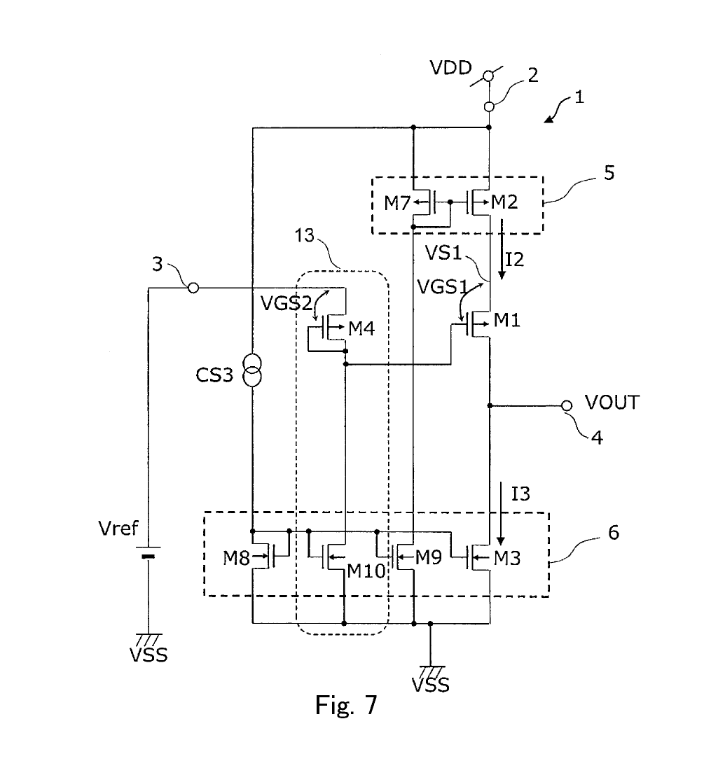

FIG. 7 is a circuit diagram showing a configuration of the voltage detecting circuit according to Modification Example of Embodiment 4 of the present invention. Modification Example of Embodiment 4 is different in configuration from Embodiment 4 shown in FIG. 6 in that the voltage shift portion 13 is interposed between the voltage input terminal 3 and the gate terminal of the PMOS transistor M1 as with the voltage detecting circuit 1 according to Embodiment 2 shown in FIG. 3. However, unlike the voltage shift portion 13 shown in FIG. 3, the resistor R1 connected to the drain terminal of the PMOS transistor M4 is replaced with an NMOS transistor M10 (tenth transistor) constituting the current mirror circuit 6.

In other words, in addition to the NMOS transistors M8, M9, and M3, the current mirror circuit 6 further includes the NMOS transistor M10 including a drain terminal (second main terminal) connected to the drain terminal of the PMOS transistor M4, a source terminal (first main terminal) connected to the ground potential VSS, and a gate terminal (control terminal) connected to the gate terminal of the NMOS transistor M8. The potential difference generating portion 14 of the voltage shift portion 13 is constituted by the NMOS transistor M10 of the current mirror circuit 6. The drain current value of the NMOS transistor M10 is set based on the gate aspect ratio of the NMOS transistor M10, the gate aspect ratio of the NMOS transistor M8 constituting the current mirror circuit 6, and the current value of the current source CS3.

In the configuration of Embodiment 2 shown in FIG. 3, since the drain current value (I3) of the NMOS transistor M3 is set by using the resistor R1, the drain current value (I3) of the NMOS transistor M3 changes in accordance with the voltage value of the reference voltage Vref applied to the voltage input terminal 3. In contrast, in the configuration shown in FIG. 7, the drain current value (I3) of the NMOS transistor M3 can be set to a constant value regardless of the voltage value of the reference voltage Vref.

As with Modification Example of Embodiment 1 shown in FIG. 2, the reference voltage Vref may be applied to the voltage input terminal 2, and the power supply voltage VDD may be applied to the voltage input terminal 3.

In the configuration of FIG. 7, the drain current value (I2) of the PMOS transistor M2 and the drain current value (I3) of the NMOS transistor M3 are set by the current source CS3. However, Modification Example of Embodiment 4 is not limited to the current source, and a unit configured to cause a current to flow to the drain terminal of the NMOS transistor M8 may be adopted. For example, a resistor may be used instead of the current source CS3.

### Embodiment 5

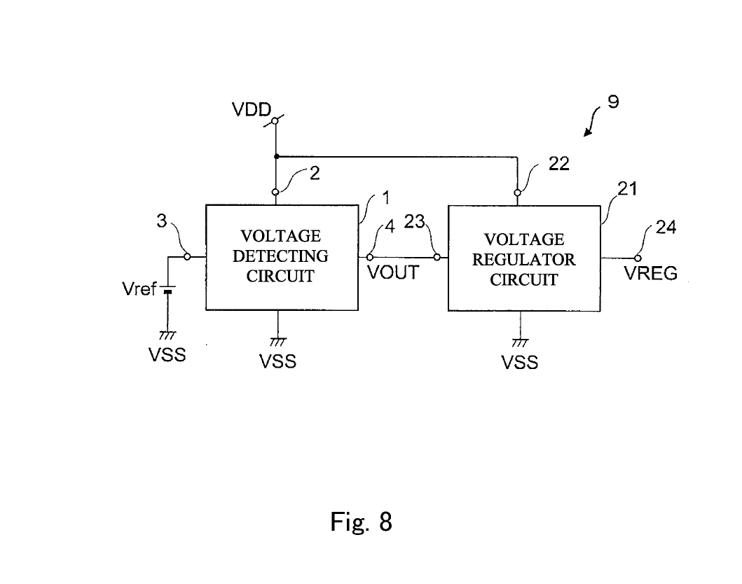

FIG. 8 is a block diagram showing a configuration example of the voltage regulator apparatus according to Embodiment 5 of the present invention. A voltage regulator apparatus 9 shown in FIG. 8 includes: the voltage detecting circuit 1 according to any one of Embodiments 1 to 4; and a voltage regulator circuit 21 configured to generate a predetermined regulator voltage VREG from the detection output voltage VOUT output from the detection output terminal 4 of the voltage detecting circuit 1 to output the predetermined regulator voltage VREG. The voltage regulator circuit 21 shown in FIG. 8 is configured to generate the predetermined regulator voltage based on the power supply voltage VDD applied to a voltage input terminal 22 and a control voltage applied to an output control terminal 23 to output the predetermined regulator voltage from an output voltage terminal 24. For example, the electric power supply of the output voltage terminal 24 is controlled in accordance with the control voltage applied to the output control terminal 23. In a case where the control voltage applied to the output control terminal 23 is the high level (for example, VDD), the regulator voltage VREG is output from the output voltage terminal 24. In contrast, in a case where the voltage applied to the output control terminal 23 is the low level (for example, VSS), the current value supplied from the output voltage terminal 24 is restricted.

Next, the operations of the voltage regulator apparatus 9 will be explained. In a case where the power supply voltage VDD is higher than the threshold of the detection target voltage in the voltage detecting circuit 1, the detection output voltage VOUT output from the detection output terminal 4 of the voltage detecting circuit 1 becomes the power supply voltage VDD, and the power supply voltage VDD is applied to the output control terminal 23 of the voltage regulator circuit 21. Therefore, in this case, the voltage regulator circuit 21 outputs the predetermined regulator voltage VREG. In contrast, in a case where the power supply voltage VDD decreases to be lower than the threshold of the detection target voltage in the voltage detecting circuit 1, the detection output voltage VOUT output from the detection output terminal 4 of the voltage detecting circuit 1 becomes the ground potential VSS, and the ground potential VSS is applied to the output control terminal 23 of the voltage regulator circuit 21. Therefore, the current value supplied from the output voltage terminal 24 of the voltage regulator circuit 21 is restricted.

### Modification Example of Embodiment 5

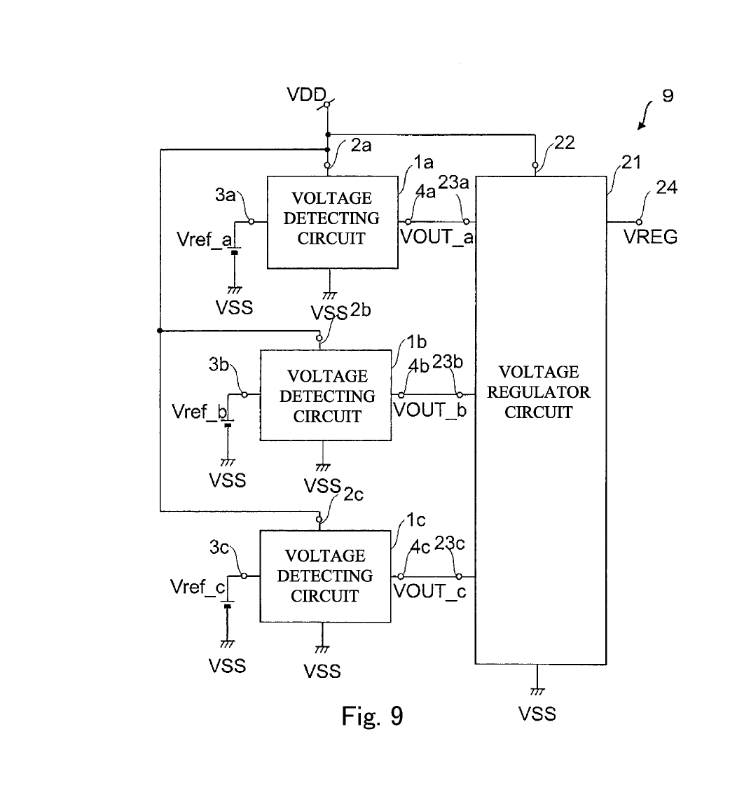

FIG. 9 is a block diagram showing another configuration example of the voltage regulator apparatus according to Embodiment 5 of the present invention. Modification Example of Embodiment 5 is different in configuration from Embodiment 5 shown in FIG. 8 in that three voltage detecting circuits 1 according to any one of Embodiments 1 to 4 are provided. Three voltage detecting circuits 1a, 1b, and 1c shown in FIG. 8 may be the circuits according to any one of Embodiments 1 to 4 or the circuits according to two or more out of Embodiments 1 to 4. Here, the thresholds of the detection target voltages of the voltage detecting circuits 1a, 1b, and 1c are different from one another.

An operating state of the voltage regulator circuit 21 changes depending on detection output voltages VOUT_a, VOUT_b, and VOUT_c of the voltage detecting circuits 1a, 1b, and 1c respectively applied to output control terminals 23a, 23b, and 23c. In a case where the power supply voltage VDD decreases, and the detection output voltage VOUT_a of the voltage detecting circuit 1a changes first, for example, the power supply voltage VDD is directly output as the regulator voltage VREG from the output voltage terminal 24 of the voltage regulator circuit 21. In a case where the power supply voltage VDD further decreases, and the detection output voltage VOUT_b of the voltage detecting circuit 1b changes next, for example, the current value supplied from the output voltage terminal 24 is restricted. In a case where the power supply voltage VDD further decreases, and the detection output voltage VOUT_c changes next, for example, the output voltage terminal 24 is open, and the electric power supply is stopped.

As above, in the configuration shown in FIG. 9, as the power supply voltage VDD decreases, the operating state of the voltage regulator circuit 21 is changed based on a plurality of thresholds of the power supply voltage VDD. The above operating state is just one example, and Modification Example of Embodiment 5 is not limited to this. In the above explanation, the number of voltage detecting circuits is three, and the number of thresholds is three. However, Modification Example of Embodiment 5 is not limited to these numbers. The reference voltages Vref of the voltage detecting circuits 1a, 1b, and 1c are respectively set to the reference voltages Vref_a, Vref_b, and Vref_c. However, a single reference voltage may be used as each of the reference voltages Vref_a, Vref_b, and Vref_c.

The voltage regulator circuit 21 may be any circuit as long as it generates a predetermined voltage from an input voltage to output the predetermined voltage. The voltage regulator circuit 21 is not limited to a switching regulator or a voltage regulator. The logic of the detection output voltage VOUT of the voltage detecting circuit 1 and the logic of the voltage applied to the output control terminal 23 of the voltage regulator circuit 21 are not limited to the above.

In the foregoing explanation, elements denoted by the reference signs M1 to M10 are the MOS transistors. However, elements denoted by the reference signs M1 to M10 are not limited to the MOS transistors and may be bipolar transistors. Generally, a “transistor” is a three-terminal signal amplifying element including two “main terminals” and one “control terminal”. The “main terminals” denote two terminals, such as a source and drain of a field-effect transistor or an emitter and collector of a bipolar transistor, through which an operating current flows. The “control terminal” denotes a terminal, such as a gate of a field-effect transistor or a base of a bipolar transistor, to which a bias voltage is applied.

From the foregoing explanation, many modifications and other embodiments of the present invention are obvious to one skilled in the art. Therefore, the foregoing explanation should be interpreted only as an example and is provided for the purpose of teaching the best mode for carrying out the present invention to one skilled in the art. The structures and/or functional details may be substantially modified within the spirit of the present invention.

### INDUSTRIAL APPLICABILITY

The present invention is useful as a voltage detecting circuit configured to detect a voltage reduction of a power supply voltage.

### REFERENCE SIGNS LIST

1, 1a, 1b, 1c voltage detecting circuit
2 voltage input terminal
3 detection output terminal
5 current mirror circuit (first current mirror circuit)
6 current mirror circuit (second current mirror circuit)
7 bias circuit
9 voltage regulator apparatus
11 current source (first current source)
12 current source (second current source)
13 voltage shift portion
14 potential difference generating portion
V2, V3 constant voltage source
M1 PMOS transistor (first transistor)
M2 PMOS transistor (second transistor)
M3 NMOS transistor (third transistor)
M4 PMOS transistor (fourth transistor)
M5 PMOS transistor (fifth transistor)
M6 NMOS transistor (sixth transistor)
M7 PMOS transistor (seventh transistor)
M8 NMOS transistor (eighth transistor)
M9 NMOS transistor (ninth transistor)
M10 NMOS transistor (tenth transistor)
R1, R2 resistor
21 voltage regulator circuit
22 voltage input terminal
23 output control terminal
24 output voltage terminal

1. A voltage detecting circuit comprising:
a first voltage input terminal to which one of a detection target voltage and a reference voltage is applied;
a second voltage input terminal to which the other of the detection target voltage and the reference voltage is applied;
a detection output terminal through which a detection output signal is output, the detection output signal indicating a logic regarding whether or not the detection target voltage is lower than the reference voltage;
a first current source including a pair of terminals, one of which is a first terminal connected to the first voltage input terminal;
a second current source including a pair of terminals, one of which is a first terminal connected to ground; and
a first transistor including a pair of main terminals that are a first main terminal connected to a second terminal of the first current source and a second main terminal connected to a second terminal of the second current source and the detection output terminal, and a control terminal connected to the second voltage input terminal, wherein
a logic level of the detection output signal is determined based on whether a voltage of the first main terminal of the first transistor is higher or lower than a voltage of the first voltage input terminal.

2. The voltage detecting circuit according to claim 1, wherein:
the first current source is constituted by a second transistor including a pair of main terminals that are a first main terminal connected to the first voltage input terminal and a second main terminal connected to the first main terminal of the first transistor, a first bias voltage being applied between the first main terminal and a control terminal of the second transistor;
the second current source is constituted by a third transistor including a pair of main terminals that are a second main terminal connected to the second main terminal of the first transistor and a first main terminal connected to the ground, a second bias voltage being applied between the first main terminal and a control terminal of the third transistor; and
a current drive ability of the second transistor is set to be higher than a current drive ability of the third transistor.

3. The voltage detecting circuit according to claim 1, further comprising a voltage shift portion provided between the second voltage input terminal and the control terminal of the first transistor, wherein
the voltage shift portion includes:
a fourth transistor including a pair of main terminals that are a first main terminal connected to the second voltage input terminal and a second main terminal connected to a control terminal of the fourth transistor and the control terminal of the first transistor; and
a potential difference generating portion including a pair of terminals that are a first terminal connected to the second main terminal of the fourth transistor and a second terminal connected to the ground, the potential difference generating portion being configured to generate a potential difference between the first main terminal and second main terminal of the fourth transistor.

4. The voltage detecting circuit according to claim 3, wherein gate aspect ratios of the first transistor and the fourth transistor are set such that a voltage difference between the first main terminal and control terminal of the fourth transistor and a voltage difference between the first main terminal and control terminal of the first transistor become equal to each other.

5. The voltage detecting circuit according to claim 3, wherein the potential difference generating portion of the voltage shift portion is constituted by a resistor.

6. The voltage detecting circuit according to claim 2, further comprising a bias circuit configured to apply the first bias voltage between the first main terminal and control terminal of the second transistor of the first current source and apply the second bias voltage between the first main terminal and control terminal of the third transistor of the second current source, wherein:
the bias circuit includes
a fifth transistor including a pair of main terminals that are a first main terminal connected to the first main terminal of the second transistor and a second main terminal connected to a control terminal of the fifth transistor and the control terminal of the second transistor,
a sixth transistor including a pair of main terminals that are a second main terminal connected to a control terminal of the sixth transistor and the control terminal of the third transistor and a first main terminal connected to the first main terminal of the third transistor, and
a resistor connected between the second main terminal of the fifth transistor and the second main terminal of the sixth transistor; and
the current drive ability of the second transistor is set to be higher than the current drive ability of the third transistor.

7. The voltage detecting circuit according to claim 2, wherein:
the first current source is constituted by a first current mirror circuit including the second transistor and a seventh transistor, the second transistor including the pair of main terminals that are the first main terminal connected to the first voltage input terminal and the second main terminal connected to the first main terminal of the first transistor, the seventh transistor including a pair of main terminals that are a first main terminal connected to the first main terminal of the second transistor and a second main terminal connected to a control terminal of the seventh transistor, and the control terminal connected to the control terminal of the second transistor;
the second current source is constituted by a second current mirror circuit including the third transistor, an eighth transistor, and a ninth transistor, the third transistor including the pair of main terminals that are the second main terminal connected to the second main terminal of the first transistor and the first main terminal connected to the ground, the eighth transistor including a pair of main terminals that are a second main terminal connected to a current source and a first main terminal connected to the ground, and a control terminal connected to the second main terminal of the eighth transistor, the ninth transistor including a pair of main terminals that are a second main terminal connected to the second main terminal of the seventh transistor and a first main terminal connected to the ground, and a control terminal connected to the control terminal of the third transistor and the control terminal of the eighth transistor; and
the current drive ability of the second transistor is set to be higher than the current drive ability of the third transistor.

8. The voltage detecting circuit according to claim 7, further comprising a voltage shift portion provided between the second voltage input terminal and the control terminal of the first transistor, wherein:
the voltage shift portion includes
a fourth transistor including a pair of main terminals that are a first main terminal connected to the second voltage input terminal and a second main terminal connected to a control terminal of the fourth transistor and the control terminal of the first transistor, and
a potential difference generating portion including a pair of terminals that are a first terminal connected to the second main terminal of the fourth transistor and a second terminal connected to the ground, the potential difference generating portion being configured to generate a potential difference between the first main terminal and second main terminal of the fourth transistor;
the second current mirror circuit further includes a tenth transistor including a pair of main terminals that are a second main terminal connected to the second main terminal of the fourth transistor and a first main terminal connected to the ground, and a control terminal connected to the control terminal of the eighth transistor; and
a potential difference generating portion of a voltage shift portion is constituted by the tenth transistor.

9. A voltage regulator apparatus comprising:
the voltage detecting circuit according to claim 1; and
a voltage regulator circuit, wherein
the voltage regulator circuit is configured such that an output therefrom is controlled in accordance with the detection output signal output from the detection output terminal of the voltage detecting circuit.

10. A voltage regulator apparatus comprising:
a plurality of voltage detecting circuits, each of which is the voltage detecting circuit according to claim 1; and
a voltage regulator circuit, wherein:
reference voltages applied to the first voltage input terminals or second voltage input terminals of the plurality of voltage detecting circuits are different from one another; and
the voltage regulator circuit is configured such that an output therefrom is controlled in accordance with the detection output signals output from the detection output terminals of the plurality of voltage detecting circuits to become one of a plurality of states
